(19) United States
(12) Patent Application Publication
(10) Pub. No.: US 2026/0123335 A1
(43) Pub. Date: Apr. 30, 2026

(54) COOLING PLATES, SYSTEM INCLUDING COOLING PLATES AND METHOD FOR CONTROLLING MOISTURE IN THE SYSTEM

(71) Applicant: ASM IP Holding B.V., Almere (NL)

(72) Inventor: Salam Harb, Scottsdale, AZ (US)

(21) Appl. No.: 19/371,104

(22) Filed: Oct. 28, 2025

Related U.S. Application Data
(60) Provisional application No. 63/714,362, filed on Oct. 31, 2024.

(51) Int. Cl. H01L 21/67; H01L 21/677; H01L 21/687

(52) U.S. Cl. CPC H10P 72/06; H10P 72/3304; H10P 72/7602

(57) ABSTRACT

A substrate processing system is provided for effective moisture control during fabrication operations. The system includes a buffer chamber with a cooling plate, which is coupled to a cryogenic pump to circulate a cryogen, such as liquid nitrogen. Residual moisture and water vapor released during substrate transfer are captured and condensed onto the cooling plate. A regeneration system monitors moisture accumulation using sensors and initiates regeneration when a set threshold is reached.

### CROSS-REFERENCE TO RELATED APPLICATIONS

This application claims priority to U.S. Provisional patent application Ser. No. 63/714,362, filed Oct. 31, 2024 and titled COOLING PLATES AS GETTER MECHANISM FOR RESIDUAL MOISTURE AND WATER VAPOR, the disclosure of which is hereby incorporated by reference in its entirety.

### FIELD OF INVENTION

The present disclosure generally relates to fabricating integrated circuit (IC) devices. Specifically, the present invention relates to using cooling plates as getter mechanism for residual moisture and water vapor.

### BACKGROUND OF THE INVENTION

Conventional substrate processing systems encounter challenges related to residual moisture and water vapor during substrate transfer operations. When substrates are moved from Equipment Front End Module (EFEM) into buffer chambers such as load lock modules (LLM) and pass-through chambers (PTC), moisture and vapor originating from the substrates can escape into these buffer chambers. This escaped moisture and vapor often becomes trapped within the chambers. The presence of residual moisture and water vapor in buffer chambers creates several problems. For example, these molecules are difficult to remove using standard vacuum pumping techniques, as they tend to adhere to chamber surfaces and substrate supports.

Existing methods for moisture removal are often complex, inefficient, or inadequate to resolve these issues. Accordingly, there is a need for an improved, simplified, and effective mechanism to capture and remove residual moisture and water vapor from buffer chambers during substrate transfer operations.

Any discussion, including discussion of problems and solutions, set forth in this section, has been included in this disclosure solely for the purpose of providing a context for the present disclosure, and should not be taken as an admission that any or all of the discussion was known at the time the invention was made or otherwise constitutes prior art.

### BRIEF SUMMARY

According to some embodiments, a substrate processing system may include a wafer handling chamber (WHC), a WHC robot disposed within the WHC and a buffer chamber coupled to the WHC. The buffer chamber may include a cooling plate and a substrate support coupled to the cooling plate. The cooling plate may be configured to capture residual moisture from a substrate resting on the substrate support. The substrate processing system may also include a cryogenic pump configured to cycle a cryogen through the cooling plate, at least one process module coupled to the WHC and a regeneration system. The WHC robot may be configured to transfer substrates between the buffer chamber and the at least one process module. The regeneration system may be configured to remove moisture accumulated on the cooling plate.

In some embodiments, the buffer chamber may be a load lock module.

In some embodiments, the buffer chamber may be a first buffer chamber, and the WHC may be a first wafer handling chamber. The substrate processing system may further include a second buffer chamber coupled to the first wafer handling chamber and a second WHC coupled to the second buffer chamber.

In some embodiments the regeneration system may include a regeneration sensor coupled to the cooling plate. The regeneration sensor may be configured to monitor a regeneration parameter. The regeneration system may also include a heating mechanism coupled to the buffer chamber. When the regeneration parameter meets or exceeds a predetermined threshold, the heating mechanism may be configured to increase a temperature of the cooling plate to desorb moisture accumulated on the cooling plate. Additionally, regeneration system may include a pump configured to pump the desorbed moisture out of the buffer chamber.

In some embodiments, the heating mechanism may be an infrared lamp.

In some embodiments, the heating mechanism may be an internal heater embedded within the cooling plate.

In some embodiments, the heating mechanism may include a purge gas introduced into the buffer chamber to increase temperature within the buffer chamber.

In some embodiments, the purge gas may be at least one of nitrogen, argon or helium.

In some embodiments, the regeneration sensor may include a residual gas analyzer (RGA) operatively coupled to the cooling plate, the regeneration parameter may include an amount of moisture accumulated on the cooling plate, and when the RGA detects that the amount of moisture accumulated on the cooling plate meets or exceeds a predetermined moisture threshold, the heating mechanism may be activated to increase the temperature of the cooling plate.

In some embodiments, the regeneration sensor may be configured to monitor an amount of time elapsed since completion of a previous regeneration cycle, and the regeneration parameter may include the amount of time elapsed, and when the amount of time elapsed meets or exceeds a predetermined time threshold, the heating mechanism may be activated to increase the temperature of the cooling plate.

In some embodiments, a temperature of cryogen may be less than 130 Kelvin.

According to some embodiments, a method for controlling moisture in a substrate processing system may include providing the substrate processing system including a buffer chamber that includes a cooling plate coupled to a cryogenic pump, circulating a cryogen through the cooling plate using the cryogenic pump to capture residual moisture from substrates received in the buffer chamber, determining whether one or more regeneration parameters meet or exceed a predetermined threshold, and when the one or more regeneration parameters meet or exceed the predetermined threshold, activating a regeneration process.

In some embodiments, the cryogen may include liquid nitrogen.

In some embodiments, activating regeneration process may include isolating the buffer chamber from other chambers of the substrate processing system, pausing circulation of the cryogen through the cooling plate, increasing temperature within the buffer chamber to a predetermined regeneration temperature to desorb residual moisture accumulated on the cooling plate, and pumping the desorbed residual moisture out of the buffer chamber.

In some embodiments, increasing temperature within the buffer chamber to the predetermined regeneration temperature may utilize at least one of: an external heater operating outside the buffer chamber; and an internal heater embedded within the cooling plate.

In some embodiments, increasing the temperature within the buffer chamber to the predetermined regeneration temperature may include introducing a purge gas into the buffer chamber.

In some embodiments, determining whether one or more regeneration parameters meet or exceed a predetermined threshold may include monitoring an amount of moisture accumulated on the cooling plate, and when the amount of moisture accumulated exceeds a predetermined amount of moisture, activating the regeneration process.

In some embodiments, monitoring the amount of moisture accumulated on the cooling plate comprises utilizing a residual gas analyzer.

According to some embodiments, a regeneration system may include a cooling plate configured to accumulate residual moisture from substrates, a regeneration pump coupled to the cooling plate, a heating mechanism coupled to the cooling plate and configured to increase the temperature of the cooling plate, and a residual gas analyzer (RGA) operatively coupled to the cooling plate and configured to monitor residual moisture accumulated on the cooling plate. When the RGA detects that the monitored residual moisture is greater than a predetermined threshold, the heating mechanism may be activated to increase the temperature of the cooling plate.

In some embodiments, the regeneration pump may be a turbo molecular pump (TMP).

A semiconductor processing system is provided. The processing system includes at least one wafer handling chamber (WHC), a WHC robot comprised within the at least one WHC, and a buffer chamber coupled to the WHC. The buffer chamber further includes a cooling plate, and at least a substrate support coupled to the cooling plate, such that the cooling plate is configured to pump moisture residue from the substrates resting on the substrate support. The cooling plate is coupled to a cryogenic pump that is configured to cycle a cryogenic through the cooling plate. At least one process module is coupled to the WHC and the WHC robot is configured to transfer substrates between the buffer chamber and the at least one process module. The processing system further includes a regeneration system that is configured to remove the accumulated moisture on the cooling plate.

A method of moisture control during substrate transfer process in a semiconductor processing system is provided. The method includes coupling a cryogenic pump to a cooling plate of a buffer chamber comprised in the semiconductor processing system. The method further includes circulating a cryogenic through the cooling plate to capture residual moisture from substrates received in the buffer chamber. The method also includes determining if one or more regeneration parameters meets or exceeds a predetermined threshold. When the one or more regeneration parameters meets or exceeds the predetermined threshold, activating a regeneration process.

A regeneration system is provided. The regeneration system includes a cooling plate accumulating residual moisture resultant from the transfer of substrates from one chamber to another of a semiconductor processing system. The system further includes a regeneration pump coupled to the cooling plate. The system also includes at least one heating mechanism coupled to the cooling plate to increase the temperature of the cooling plate. The regeneration system also includes a residual gas analyzer coupled to the cooling plate. The RGA is configured to monitor residual moisture accumulated on the cooling plate. When the monitored pressure is greater than a predetermined threshold, the heating mechanism is activated to increase the temperature of the cooling plate.

This summary is provided to introduce a selection of concepts in a simplified form. These concepts are described in further detail in the detailed description of examples of the disclosure below. This summary is not intended to identify key features or essential features of the claimed subject matter, nor is it intended to be used to limit the scope of the claimed subject matter.

### BRIEF DESCRIPTION OF DRAWINGS

These and other features, aspects, and advantages of the invention disclosed herein are described below with reference to the drawings of certain example embodiments, which are intended to illustrate and not to limit the invention.

FIG. 1 illustrates a top view of a substrate processing system in accordance with some embodiments of the invention.

FIG. 2 illustrates a cross-sectional view of the substrate processing system illustrated in FIG. 1 in accordance with some embodiments of the invention.

FIG. 3 is a flow diagram of a method of moisture control during substrate transfer in the substrate processing system illustrated in FIG. 1 in accordance with some embodiments of the invention.

It will be appreciated that elements in the figures are illustrated for simplicity and clarity and have not necessarily been drawn to scale. For example, the relative size of some of the elements in the figures may be exaggerated relative to other elements to help improve understanding of illustrated embodiments of the present disclosure.

### DETAILED DESCRIPTION

Reference will now be made to the drawings wherein like reference numerals identify similar structural features or aspects throughout the disclosure. Systems and methods discussed herein may be in substrate processing systems employed to fabricate integrated circuit (IC) devices, such as in substrate processing systems employed to deposit material layers using chemical vapor deposition (CVD) and/or atomic layer deposition (ALD) techniques during the fabrication of IC devices (e.g., logic and/or memory devices), though the present disclosure is not limited to any substrate processing operation or to the fabrication of any particular device. As used herein the term “and/or” includes any and all combinations of one or more of the associated listed items.

As used herein, the term “substrate” may refer to any underlying material or materials, including any underlying material or materials that may be modified, or upon which, a device, a circuit, or a film may be formed. The “substrate” may be continuous or non-continuous; rigid or flexible; solid or porous; and combinations thereof. The substrate may be in any form, such as a powder, a plate, or a workpiece. Substrates in the form of a plate may include wafers in various shapes and sizes. Wafers may be 200 millimeters in diameter, 300 millimeters, or even 450 millimeters in diameter. Substrates may be formed from one or more semiconductor materials including by way of non-limiting example silicon, silicon germanium, silicon oxide, gallium arsenide, gallium nitride and/or silicon carbide.

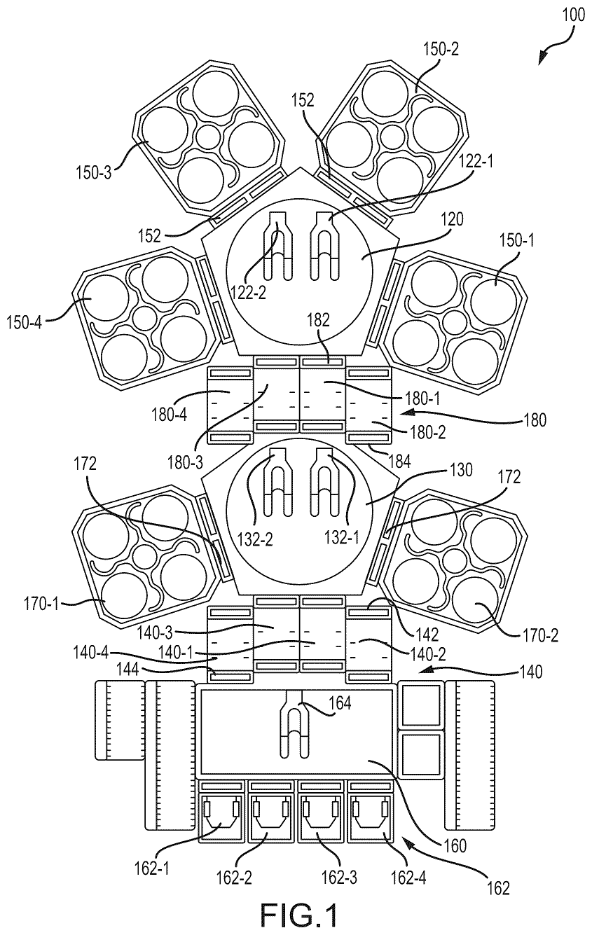

FIG. 1 illustrates a top view of a substrate processing system 100 (also referred to as a processing system). The substrate processing system 100 may be configured to receive a front opening unified pod (FOUP) (e.g., 162-1, 162-2, 162-3 or 162-4), which serves as a carrier for substrates during transfer. In example embodiments, FOUP 162 may include at least four pods 162-1, 162-2, 162-3 and 162-4. Processing system 100 may also include an equipment front end module (EFEM) 160, load lock module (LLM) 140, and at least a first wafer handling chamber (WHC) 130. Substrates contained within FOUP (e.g., 162-1, 162-2, 162-3 or 162-4) may be accessed by the substrate processing system 100. The EFEM 160 may include a front-end robot 164 that is configured to obtain substrates from the FOUP (e.g., 162-1, 162-2, 162-3 or 162-4) and transport those substrates to the LLM 140. As shown in FIG. 1, in example embodiments, front-end robot 164 may extend through one or more gate valves 144 to place substrates into LLM 140.

Processing system 100 may further include one or more processing modules (e.g., 170-1 or 170-2) that may be coupled to first WHC 130. First WHC 130 may further include at least one robot (e.g., 132-1 or 132-2). In example embodiments, first WHC 130 may include multiple robots (e.g., robot 132-1 and 132-2). In further embodiments, robots 132-1 and 132-2 may be a single arm robot or a dual arm robot. Robots 132-1 and 132-2 may be configured to collect substrates from LLM 140 and transport those substrates to first WHC 130 via gate valves 142. In example embodiments, substrates may then be transported (by robot(s) 132-1 and/or 132-2) to processing modules 170-1 and 170-2 for processing (e.g., deposition) by extending robot(s) 132-1 and/or 132-2 through gate valves 172.

In example embodiments, processing system 100 may further include a pass-through chamber (PTC) 180 and a second WHC 120. Processing system 100 may further include processing modules 150-1, 150-2, 150-3 and 150-4 for processing (e.g., deposition) that are coupled to second WHC 120. Individual chambers of PTC (e.g., 180-1, 180-2, 180-3 and 180-4) of PTC 180 may function in a manner similar to chambers (e.g., 140-1, 140-2, 140-3 or 140-4) of LLM 140. In such example embodiments, some substrates may be transported from first WHC 130 to pass-through chamber (PTC) 180 via gate valves 184. Further, second WHC 120 may include at least one robot (e.g., 122-1 or 122-2). In example embodiments, second WHC 120 may include multiple robots (such as robots 122-1 and 122-2). In example embodiments, robots 122-1 and 122-2 may be a single arm robot or a dual arm robot. Like robots 132-1 and 132-2, robots 122-1 and 122-2 may be configured to collect substrates from PTC 180 and transport those substrates to second WHC 120 via gate valves 182. In example embodiments, substrates may then be transported (by robot(s) 122-1 and 122-2) to processing modules (e.g., 150-1, 150-2, 150-3 and 150-4) via gate valves 152 for processing (e.g., deposition).

Referring to FIG. 1, first WHC 130 may be coupled to two processing modules 170-1 and 170-2. However, in some example embodiments, first WHC 130 may have the capability to support more than two processing modules (for example, four processing modules). In example embodiments, second WHC 120 may be coupled to four processing modules 150-1, 150-2, 150-3 and 150-4. Thus, in example embodiments (such as the one shown in FIG. 1), processing system 100 may include six processing modules (170-1, 170-2, 150-1, 150-2, 150-3 and 150-4).

After processing, substrates may be transported back to FOUP(s) 162 (e.g., 162-1, 162-2, 162-3 and/or 162-4). That is, substrates processed in processing modules 150-1, 150-2, 150-3 and/or 150-4 may be collected by robot(s) 122-1 and 122-2 in second WHC 120 and placed in a chamber (e.g., 180-1, 180-2, 180-3 or 180-4) of the PTC 180. Substrates may then be picked up from PTC 180 by robots 132-1 and 132-2 in first WHC 130 and placed in one of chambers (e.g., 140-1, 140-2, 140-3 or 140-4) of LLM 140. Finally, substrates may be collected by front-end robot 164 and transported back to FOUP 162 (e.g., 162-1, 162-2, 162-3 or 162-4). Similarly, after processing, substrates processed in processing modules (such as 170-1 and/or 170-2) may be collected by robot(s) 132-1 and 132-2 in first WHC 130 and placed in one of chambers (e.g., 140-1, 140-2, 140-3 or 140-4) of the LLM 140. These substrates may be collected by front-end robot 164 and transported back to FOUP 162 (e.g., 162-1, 162-2, 162-3 or 162-4).

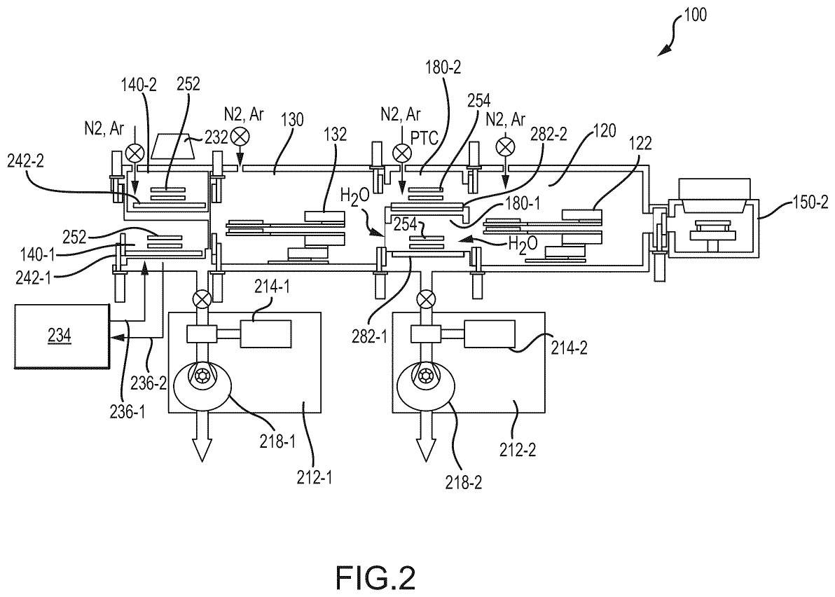

Referring now to FIG. 2, a cross-sectional view of processing system 100 is illustrated. As shown in FIG. 2, LLM 140 may include an upper chamber 140-2 and a lower chamber 140-1. Similarly, PTC 180 may include an upper chamber 180-1 and a lower chamber 180-2. Further, in example embodiments, LLM 140 may be split into two sections with each section including an upper chamber and a lower chamber (see 140-1, 140-2, 140-3 and 140-4 in FIG. 1). Similarly, in example embodiments, PTC 180 may be split in two sections with each section including an upper chamber and lower chamber (see 180-1, 180-2, 180-3 and 180-4 in FIG. 1). Since FIG. 2 illustrates a cross-sectional view, only one upper chamber 140-2 and one lower chamber 140-1 of LLM 140 and only one upper chamber 180-2 and one lower chamber 180-1 of PTC 180 are seen. However, the second upper chamber (e.g., 140-4) and second lower chamber (e.g., 140-3) of LLM 140 may be designed and may function in a manner similar to upper chamber 140-2 and lower chamber 140-1. Similarly, the second upper chamber (e.g., 180-4) and second lower chamber (e.g., 180-3) of PTC 180 may be designed and may function in a manner similar to upper chamber 180-2 and lower chamber 180-1.

As further illustrated in FIG. 2, each of the chambers in LLM 140 and PTC 180 include one or more substrate supports 252 (also referred to as wafer supports). Substrate supports 252 are configured to accommodate incoming substrates within the respective chambers. Thus, when one or more substrate is received in LLM 140 from the EFEM 160 or first WHC 130, that substrate(s) may be placed on one of the substrate supports 252. In example embodiments, each chamber of LLM 140 may include multiple substrate supports 252. Similarly, when one or more substrates is received in PTC 180 from the first WHC 130 or second WHC 120, that substrate(s) may be placed on one of the substrate supports 254. In example embodiments, each chamber of PTC 180 may include multiple substrate supports 254.

Further, LLM 140 may include a lower cooling plate 242-1 in lower chamber 140-1 and an upper cooling plate 242-2 in upper chamber 140-2. The lower cooling plate 242-1 may be coupled to the substrate supports 252 disposed in lower chamber 140-1, and the upper cooling plate 242-2 may be coupled to the substrate supports 252 disposed in upper chamber 140-2. Each of the lower cooling plate 242-1 and the upper cooling plate 242-2 may be configured to capture residual moisture from substrates disposed on the substrate supports 252 thereon and/or to capture residual moisture in the chamber (e.g., the lower chamber 140-1 or the upper chamber 140-2) resultant from substrate transfer thereon. Similarly, PTC 180 may include a lower cooling plate 282-1 in lower chamber 180-1 and an upper cooling plate 282-2 in upper chamber 180-2. The cooling plates (e.g., 242-1, 242-2, 282-1 and 282-2) may be configured to cool processed substrates that are coming out of the process module. The lower cooling plate 282-1 may be coupled to the substrate supports 254 disposed in the lower chamber 180-1, and the upper cooling plate 282-2 may be coupled to the substrate supports 254 disposed in upper chamber 180-2. Each of the lower cooling plate 282-1 and the upper cooling plate 282-2 may be configured to capture residual moisture from substrates disposed on the substrate supports 254 thereon and/or to capture residual moisture in the chamber (e.g., the lower chamber 180-1 or the upper chamber 180-2) resultant from substrate transfer thereon.

As shown in FIG. 2, cooling plates 242-1 and 242-2, and cooling plates 282-1 and 282-2 are further coupled to a cryogenic pump 234. Accordingly, a cryogenic material (also referred to as a cryogen, for example, liquid nitrogen) is pumped into LLM 140 and/or PTC 180 to bring the temperature within LLM 140 and/or PTC 180 significantly down to cool down the substrates. As shown by arrows 236-1 and 236-2, the cryogenic material may be cycled through LLM 140 and/or PTC 180 to decrease the temperature inside the respective chambers. In some embodiments, the cryogenic material may be cycled through the cooling plates (e.g., 242-1, 242-2, 282-1 and 282-2). In example embodiments, cryogenic pump 234 may be external to the processing system 100. In example embodiments, a temperature of the cryogenic material (also referred to as a cryogenic temperature) may be less than zero degrees Celsius. In example embodiments, the temperature of the cryogenic material may be less than 130 Kelvin. In example embodiments, cooling down the substrates to a cryogenic temperature condenses partial pressure of moisture (i.e. H₂O) below 1 e−7 Torr. In the context of the present invention, “cryogenic material” or “cryogen” refer to any material utilized to achieve or sustain cryogenic temperatures and may include, but is not limited to, liquid nitrogen, liquid helium, or other low-temperature substances suitable for the intended application.

Accordingly, any residual moisture resultant from substrate transfer (such as from EFEM to first WHC 130 via LLM 140 or from transfer to first WHC 130 via PTC 180) may be captured by cooling plate(s) (i.e., plates 242-1, 242-2, 282-1 and/or 282-2) and may be accumulated on those cooling plate(s). However, cooling plate(s) 242-1, 242-2, 282-1 and 282-2 may eventually be saturated and require regeneration to desorb residual moisture accumulated on the cooling plate. In example embodiments, a regeneration process may be activated when a regeneration requirement is met.

In example embodiments, the substrate processing system 100 may further include saturation sensors 214-1 and 214-2 (also referred to as regeneration sensors) coupled to cooling plates 242-1, 242-2 and 282-1, 282-2. In example embodiments, the saturation sensors 214-1 and 214-2 may measure the amount of moisture accumulated on cooling plate(s) 242-1, 242-2, 282-1 and 282-2. When the amount of accumulated moisture measured by the saturation sensor is determined to exceed a predetermined saturation threshold, regeneration process may be activated. In example embodiments, the saturation sensors 214-1 and 214-2 may include a differential pumping residual gas analyzer (RGA). This RGA may be used to monitor partial pressure of H₂O on the cooling plate(s) 242-1, 242-2, 282-1 and 282-2. RGA results are indicative of the amount of moisture on the cooling plate(s) 242-1, 242-2, 282-1 and 282-2 and its comparison with a predetermined saturation threshold may then be used to determine regeneration frequencies. In example embodiments, saturation sensor 214-1 and 214-2 may be included in the sampling chamber 212-1 and/or sampling chamber 212-2. In example embodiments, sampling chambers 2120-1 and 212-2 may include a different spectrum analyzer.

In example embodiments, regeneration process may be activated based on the amount of time elapsed between regeneration cycles. That is, when the amount of time elapsed subsequent to completion of regeneration process meets or exceeds (e.g., meets) a predetermined regeneration time threshold, regeneration process is activated.

When it is determined that cooling plates 242-1 and/or 242-2 are saturated, regeneration process may be activated. Gate valves 142 and 144 may be moved in a closed position to isolate LLM 140 (and consequently, cooling plates 242-1 and/or 242-2) from the first WHC 130 and EFEM 160. Similarly, when it is determined that cooling plates 281-1 and/or 282-2 are saturated, regeneration may be activated for PTC 180. Gate valves 182 and 184 may be moved in a closed position to isolate PTC 180 (and consequently, cooling plates 282-1 and 282-2) from first WHC 130 and second WHC 120. Cryogenic pump 234 may be shut off to pause recirculation of cryogenic material in the respective chamber.

Further, the temperature of the cooling plate may be raised to sublimate adsorbed moisture. In example embodiments, the regeneration temperature may be room temperature. In example embodiments, the temperature may be raised by operating a heating mechanism 232. In example embodiments, heating mechanism 232 (e.g., heater(s)) may be embedded into the cooling plate(s) 242-1, 242-2, 282-1 and/or 282-2. In example embodiments, heating mechanism 232 may be an external heater (such as an infrared lamp) that is used to provide heat to cooling plate(s) 242-1, 242-2, 282-1 and/or 282-2. This external heater may be coupled to the respective chamber (i.e. LLM 140 or PTC 180). In example embodiments, temperature in the respective chamber may be raised with aid of a purge gas (for example, hot Nitrogen (N2) or Argon (Ar) or Helium). In such examples, the temperature of the cooling plate may be increased, and the buffer chamber may be brought to atmospheric pressure (atm) to facilitate desorption of residual moisture accumulated on the cooling plate.

This desorbed moisture can then be pumped out of the chambers of the LLM 140 and PTC 180 (and consequently, cooling plates 242-1, 242-2 and 282-1, 282-2). In example embodiments, desorbed moisture may be pumped out from the cooling plates of the respective chamber via a regeneration pump 218-1 and/or 218-2. Regeneration pump 218-1 may be coupled to a chamber of LLM 140 and regeneration pump 218-2 may be coupled to PTC 180. In some example embodiments, regeneration pump 218-1 and/or 218-2 may be a turbo molecular pump (TMP) that may be operated in very low pressure to pump quickly and efficiently. In example embodiments, after the desorbed moisture has been pumped out, cooling plates 242-1, 242-2 and 282-1, 282-2 in chambers of LLM 140 and PTC 180 can be cleaned for reuse. A regeneration system refers to a system that includes elements (e.g., saturation sensors 214-1 and 214-2 and regeneration pumps 218-1 and 218-2) involved in the regeneration process.

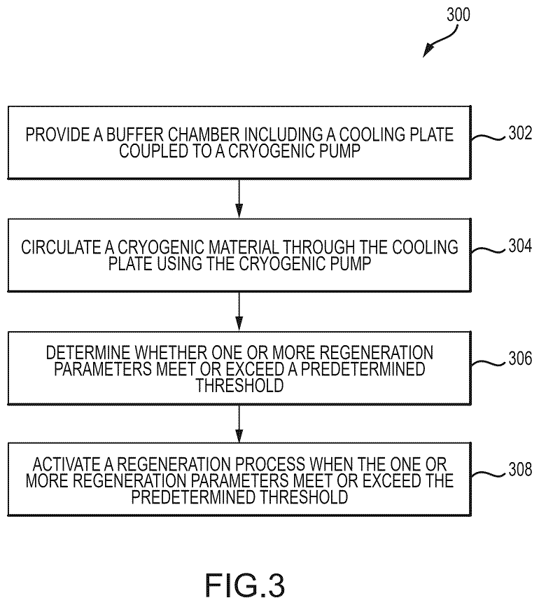

With reference to FIG. 3, a method 300 for controlling moisture during substrate transfer is provided. The method 300 may include providing the substrate processing system including a buffer chamber that includes a cooling plate coupled to a cryogenic pump (Block 302). The cryogenic pump may be coupled to the cooling plate before following operations are performed. The method 300 may also include circulating a cryogenic material through the cooling plate to capture residual moisture from substrates in the buffer chamber (Block 304). In example embodiments, cryogenic material may be liquid nitrogen.

Further, the method 300 may include determining whether one or more regeneration parameters meet or exceed a predetermined threshold (Block 306). In example embodiments, the regeneration parameter(s) may include the amount of moisture accumulated on the cooling plate. Accordingly, example embodiments of method 300 may further include monitoring the amount of moisture accumulated on the cooling plate. The method 300 may also include, when the one or more regeneration parameters (e.g., an amount of moisture accumulated on the cooling plate) meet or exceed the predetermined threshold (e.g., a predetermined amount of moisture), activating the regeneration process (Block 308). In example embodiments, residual gas analyzer may be coupled to the cooling plate to monitor pressure due to accumulation of the moisture on the cooling plate. When the pressure exceeds a predetermined threshold, regeneration process may be activated.

In example embodiments, regeneration parameter may include time. Thus, the method 300 may further include monitoring the time elapsed between regeneration cycles. Accordingly, the time elapsed from a previous regeneration process is monitored and when the time duration meets or exceeds (e.g., meets) a predetermined regeneration time threshold, the regeneration process may be activated.

When the one or more regeneration parameters meets or exceeds the predetermined threshold, a regeneration process may be activated. In example embodiments, method 300 may further include isolating buffer chamber from other chambers of substrate processing system, pausing circulation of the cryogenic material through the cooling plate, increasing temperature within the buffer chamber to a predetermined regeneration temperature to desorb residual moisture accumulated on the cooling plate and pumping the dissolved residual moisture out of the buffer chamber.

In example embodiments of method 300, increasing temperature within the buffer chamber to a predetermined regeneration temperature may further include utilizing a heating mechanism. In example embodiments, the heating mechanism may include an external heater operating outside the buffer chamber (such as an infrared (IR) lamp). In example embodiments, the heating mechanism may include an internal heater that may be embedded within the cooling plates. In example embodiments, the heating mechanism may include introducing a purge gas in the buffer chamber to aid increase in temperature within the buffer chamber.

The steps illustrated in FIG. 3 can be performed in various orders and are not limited to the specific sequence depicted. In some embodiments, certain steps may be omitted, combined, or repeated, and the order of execution may be modified based on process requirements. The flow chart is intended to provide an example of possible process flows and should not be construed as limiting the scope of the invention to any particular sequence of steps.

Although this disclosure has been provided in the context of certain embodiments and examples, it will be understood by those skilled in the art that the disclosure extends beyond the specifically described embodiments to other alternative embodiments and/or uses of the embodiments and obvious modifications and equivalents thereof. In addition, while several variations of the embodiments of the disclosure have been shown and described in detail, other modifications, which are within the scope of this disclosure, will be readily apparent to those of skill in the art based upon this disclosure. It is also contemplated that various combinations or sub-combinations of the specific features and aspects of the embodiments may be made and still fall within the scope of the disclosure. It should be understood that various features and aspects of the disclosed embodiments can be combined with, or substituted for, one another in order to form varying modes of the embodiments of the disclosure. Thus, it is intended that the scope of the disclosure should not be limited by the particular embodiments described above.

The headings provided herein, if any, are for convenience only and do not necessarily affect the scope or meaning of the devices and methods disclosed herein.

1. A substrate processing system comprising:
a wafer handling chamber (WHC);
a WHC robot disposed within the WHC;
a buffer chamber coupled to the WHC, the buffer chamber comprising:
a cooling plate; and
a substrate support coupled to the cooling plate, wherein the cooling plate is configured to capture residual moisture from a substrate resting on the substrate support;
a cryogenic pump configured to cycle a cryogen through the cooling plate;
at least one process module coupled to the WHC, wherein the WHC robot is configured to transfer substrates between the buffer chamber and the at least one process module; and
a regeneration system, wherein the regeneration system is configured to remove moisture accumulated on the cooling plate.

2. The substrate processing system of claim 1, wherein the buffer chamber is a load lock module.

3. The substrate processing system of claim 2, wherein the buffer chamber is a first buffer chamber, and the WHC is a first wafer handling chamber, and
wherein the substrate processing system further comprises:
a second buffer chamber coupled to the first wafer handling chamber; and
a second WHC coupled to the second buffer chamber.

4. The substrate processing system of claim 1, wherein the regeneration system comprises:
a regeneration sensor coupled to the cooling plate, wherein the regeneration sensor is configured to monitor a regeneration parameter;
a heating mechanism coupled to the buffer chamber, wherein, when the regeneration parameter meets or exceeds a predetermined threshold, the heating mechanism is configured to increase a temperature of the cooling plate to desorb moisture accumulated on the cooling plate; and
a pump configured to pump the desorbed moisture out of the buffer chamber.

5. The substrate processing system of claim 4, wherein the heating mechanism is an infrared lamp.

6. The substrate processing system of claim 4, wherein the heating mechanism is an internal heater embedded within the cooling plate.

7. The substrate processing system of claim 4, wherein the heating mechanism comprises a purge gas introduced into the buffer chamber to increase a temperature within the buffer chamber.

8. The substrate processing system of claim 7, wherein the purge gas is at least one of nitrogen, argon or helium.

9. The substrate processing system of claim 4, wherein the regeneration sensor comprises a residual gas analyzer (RGA) operatively coupled to the cooling plate,
wherein the regeneration parameter comprises an amount of moisture accumulated on the cooling plate, and
wherein, when the RGA detects that the amount of moisture accumulated on the cooling plate meets or exceeds a predetermined moisture threshold, the heating mechanism is activated to increase the temperature of the cooling plate.

10. The substrate processing system of claim 4, wherein the regeneration sensor is configured to monitor an amount of time elapsed since completion of a previous regeneration cycle, and the regeneration parameter comprises the amount of time elapsed, and wherein, when the amount of time elapsed meets or exceeds a predetermined time threshold, the heating mechanism is activated to increase the temperature of the cooling plate.

11. The substrate processing system of claim 1, wherein a temperature of cryogen is less than 130 Kelvin.

12. A method for controlling moisture in a substrate processing system, the method comprising:
providing the substrate processing system comprising a buffer chamber that comprises a cooling plate coupled to a cryogenic pump;
circulating a cryogen through the cooling plate using the cryogenic pump to capture residual moisture from substrates received in the buffer chamber;
determining whether one or more regeneration parameters meet or exceed a predetermined threshold; and
when the one or more regeneration parameters meet or exceed the predetermined threshold, activating a regeneration process.

13. The method of claim 12, wherein the cryogen comprises liquid nitrogen.

14. The method of claim 12, wherein activating regeneration process comprises:
isolating the buffer chamber from other chambers of the substrate processing system;
pausing circulation of the cryogen through the cooling plate;
increasing a temperature within the buffer chamber to a predetermined regeneration temperature to desorb residual moisture accumulated on the cooling plate; and
pumping the desorbed residual moisture out of the buffer chamber.

15. The method of claim 14, wherein increasing the temperature within the buffer chamber to the predetermined regeneration temperature utilizes at least one of:
an external heater operating outside the buffer chamber; and
an internal heater embedded within the cooling plate.

16. The method of claim 14, wherein increasing the temperature within the buffer chamber to the predetermined regeneration temperature comprises introducing a purge gas into the buffer chamber.

17. The method of claim 12, wherein determining whether the one or more regeneration parameters meet or exceed the predetermined threshold comprises:
monitoring an amount of moisture accumulated on the cooling plate; and
when the amount of moisture accumulated exceeds a predetermined amount of moisture, activating the regeneration process.

18. The method of claim 17, wherein monitoring the amount of moisture accumulated on the cooling plate comprises utilizing a residual gas analyzer.

19. A regeneration system comprising:
a cooling plate configured to accumulate residual moisture from substrates;
a regeneration pump coupled to the cooling plate;
a heating mechanism coupled to the cooling plate and configured to increase a temperature of the cooling plate; and
a residual gas analyzer (RGA) operatively coupled to the cooling plate and configured to monitor residual moisture accumulated on the cooling plate,
wherein when the RGA detects that the monitored residual moisture is greater than a predetermined threshold, the heating mechanism is activated to increase the temperature of the cooling plate.

20. The regeneration system of claim 19, wherein the regeneration pump is a turbo molecular pump (TMP).
